(19) United States
(12) Patent Application Publication
(10) Pub. No.: US 2026/0221959 A1
(43) Pub. Date: Jul. 30, 2026

(54) Circuits and Methods for Transmitting Data Over 3D Semiconductor Die Interconnects

(71) Applicant: Blue Cheetah Analog Design, Inc., Sunnyvale, CA (US)

(72) Inventors: Elad Alon, Orinda, CA (US); John Lupienski, Apex, NC (US); John L. Kusching, Clearwater Beach, FL (US)

(21) Appl. No.: 19/038,208

(22) Filed: Jan. 27, 2025

(51) Int. Cl. H03K 5/135; H03K 3/037; H03K 5/131; H03K 5/133; H03K 19/17736; H03K 19/20; H10D 88/00

(52) U.S. Cl. CPC H03K 5/135; H03K 3/037; H03K 5/131; H03K 5/133; H03K 19/1774; H03K 19/17744; H03K 19/20; H10D 88/00

(57) ABSTRACT

A circuit and method for providing matched clocks for transmitting data in bundles from a first semiconductor die to a second semiconductor die. The circuit generates a source clock from a system clock, which is distributed to a clock circuit. The clock circuit generates a bundle clock, which retimes a bundle of data lines and transmits the data to a die interconnect on the rising edge of the bundle clock. The receiving die receives the bundle clock and the received bundle data over the interconnect. The received bundle data is retimed on the rising edge of the received bundle clock. The circuit can include an enable of the bundle clock based on the transmit data within a bundle transitioning between clock cycles.

### TECHNICAL AREA

The present invention relates to the field of 2.5/3D packaged Integrated Circuit (IC) devices. In particular, but not by way of limitation, the present invention discloses circuits for synchronizing clocking and data transfer between semiconductor devices of multilayer or Three-Dimensional Integrated circuits (3D-IC).

### BACKGROUND

The increasing rise in functionality and performance of ICs has, in part, been due to the “scaling,” i.e., component sizes within ICs. These component sizes have been reduced (“scaled”) with every successive generation of technology. With “scaling,” transistor performance and density typically improve, contributing to increases in IC performance and functionality. However, wires or other interconnects connecting transistors degrade in performance with “scaling.” Currently, wires dominate the performance, functionality, and power consumption of ICs.

3D stacking of semiconductor devices or chips is one avenue to tackle the wire issues. By arranging transistors in 3 dimensions instead of 2 dimensions (as was the case in the 1990s), the transistors in ICs can be placed closer to each other. This arrangement reduces wire lengths and keeps wiring delay low.

Within systems having multiple dies in a 2.5/3D architecture, the goal is to run the circuits within the dies as closely as possible to minimize delays and increase speeds. However, going across the 3D boundaries has the challenge that there may be different process technologies, voltages, and temperatures across die boundaries, causing variances between a clock forwarded and data forwarded between dies. The challenge is to center the clock inside the data window. Given that the clock path through the system and the data path differ and that there can be a large clock fanout to a large number of IO cells, it can be a challenge to maintain clock and data alignment for a large number of interconnects between dies.

FIG. 1 is a prior art illustration of circuit 100 attempting to match the data transmission and clock transmission from semiconductor Die-1 101 to Die-2 102 through die interconnects 130 and 131. In this example, transmit data 111 between Die-1 101 and Die-2 102 is input into clocked flip-flop 112. The clocked flip-flop 112, located at the end of a buffer chain 121, is clocked by a clock signal 122. The output of the clocked flip-flop 112 is input into a driver component 113. The driver component 113 drives the data signal 114 across die interconnects 130 from Die-1 101 to Die-2 102. The received data is input to buffer 141. The output of the buffer 141 is connected to the input of clocked flip-flop 142. The clocked flip-flop 142 is clocked by the clock 153, which outputs receive data 143. Clock 153 is generated from the clock 126 received over the die interconnect 131, which is received by buffer 151 and input into buffer chain 152. The output of buffer chain 152 is also the receive clock 153 on Die-2 102. The challenge of the prior-art circuit is matching the delay of buffer chain 121 with the delay of buffer chain 152 over multiple data lines.

The clock signal 122 is generated by inputting a system clock 120 from Die-1 101 into a buffer chain 121. The system clock 120 is input into delay element 123. The delay element 123 is designed to replicate the delay of flip-flop 112. The delay element 123 generates a clock output 124, which is input into a clock driver 125, driving a transmit clock 126 to the Die-2 102 via die interconnect 131.

The problem with this circuit is that differing fabrication process, voltage, and temperature conditions between dies can result in variations in the timing between a bundle of clocks and the data transmission lines. One solution to avoid clock and data timing mismatch is to reduce the clocking speed to ensure sufficient timing margins in latching the data. This solution has the disadvantage of reducing the transfer data rate. Thus, circuits are needed to interconnect semiconductor dies in a 2.5/3D structure while matching the clock distribution delay between the transmitting and the receiving die for up to hundreds of data lines.

### SUMMARY

A circuit is presented, providing matched clocks for transmitting data using bundles of lines from a first semiconductor die to a second die. The circuit comprises a first semiconductor die having a source-clock circuit, a bundle-clock circuit, and a data-bundle clock circuit. The source-clock circuit receives a system clock and outputs a source clock.

The bundle-clock circuit generates a transmit-bundle clock distributed to the data-bundle circuits and to the bundle-clock die interconnect. The transmit-bundle clock output is generated from the source clock and is matched to a data bundle.

In one embodiment, the data-bundle circuit inputs multiple transmit data lines into a set of clocked-retiming elements (one element for each line). However, a single data line can be input in a clocked-retiming element. The outputs of the clocked-retiming elements are triggered by the rising edge of the transmit-bundle clock, generating the transmit data sent to multiple data-bundle die interconnects. The transmit-bundle clock is delayed to provide a matched transmit-bundle clock that is sent to the second die over the bundle-clock die interconnects.

The first semiconductor die circuit can include a clock circuit configured to generate a second transmit clock, which receives the source clock and outputs the second transmit clock to a receive clock die interconnect. The second transmit clock, which has substantially the same delay as the interconnect transmit-bundle clock, matches the received data on the second die circuit.

The number of transmit data lines and associated receive data lines can vary, typically between sixteen and twenty lines. In another embodiment, the bundle-clock circuit is enabled only when the data on the data lines transition.

The second die circuit includes clocked-retiming elements receiving the transmitted data sent across the die interconnects. The clocked-retiming elements on the second die are configured to trigger on the rising edge of the bundle clock received from die one over the interconnects.

### BRIEF DESCRIPTION OF THE DRAWINGS

The drawings are not necessarily drawn to scale, like numerals, and describe substantially similar components throughout the several views. Numerals with different letter suffixes represent different instances of substantially similar components. The drawings illustrate generally, by way of example, but not by way of limitation, various embodiments discussed in the present document.

FIG. 1 is a schematic block diagram of a prior art system for transferring data with a matched clock between two semiconductor dies.

FIG. 2 is a schematic block diagram illustrating a simplified view of a system for transferring a bundle of data and a matched clock between one semiconductor die and another die.

FIG. 3 is a schematic block diagram illustrating a system for transferring bundles of data and a matched clock between one semiconductor die and another die.

FIG. 4 is a schematic block diagram illustrating the control of enabling a source clock for a bundle-clock circuit and data-bundle circuit.

FIG. 5 is a schematic block diagram illustrating control to enable a source clock.

### DETAILED DESCRIPTION

The following detailed description includes references to the accompanying drawings, which form a part of the detailed description. The drawings show illustrations in accordance with example embodiments. These embodiments, which are also referred to herein as “examples,” are described in enough detail to enable those skilled in the art to practice the invention. It will be apparent to one skilled in the art that specific details in the example embodiments are not required in order to practice the present invention. The example embodiments may be combined, other embodiments may be utilized, or structural, logical, and electrical changes may be made without departing from the scope of what is claimed. The following detailed description is, therefore, not to be taken in a limiting sense, and the scope is defined by the appended claims and their equivalents.

In this document, the terms “a” or “an” are used, as is common in patent documents, to include one or more than one. In this document, the term “or” is used to refer to a nonexclusive or, such that “A or B” includes “A but not B,” “B but not A,” and “A and B,” unless otherwise indicated. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

Circuits and systems for synchronizing transmission data across bundles of data lines between two semiconductor dies using a single clock are disclosed. This synchronization is essential in 2.5/3D architectures and where large parallel data paths are required. The invention is directed at eliminating the need for the clock distribution needed on the transmit side and for the clock distribution to be similar to the clock distribution on the receiving side. Specifically, the goal is to eliminate the clock distribution on the receive side (Die-2) that would otherwise need to fan out to many data receivers. This removes the timing mismatch between the transmit and receive clock distribution, thereby making the whole system more robust. There is a clock distribution on the transmit side shared by all the transmit lines in a bundle. Any delay variation of that shared part is common for the data within a bundle and clock but does not impact timing margins.

One of the benefits of this approach is that the need to match circuitry on the two dies is eliminated. The semiconductor circuits on two dies can be fabricated using different fabrication technologies. This capability provides the benefit of being able to replace one of the dies without having to redesign the other die.

The term matched clock is used within the specification to mean that the timing variances of a clock with respect to timing variances of data lines of an associated bundle are substantially matched. As used, “substantially matched” is defined to mean that for all the data lines in a bundle, a clock can be timed to meet the input data setup times for all the clocked-retiming elements in a bundle.

FIG. 2 is a simplified illustration of circuit 200 used to match the data transmission data and clock transmission from semiconductor Die-1 201 to semiconductor Die-2 202 through the data and clock die interconnects 230 and 231. In this example, data 211 to be transmitted between Die-1 201 and Die-2 202 is input into clocked-retiming element 212. For the purpose of this embodiment and other embodiments of this invention, a clocked-retiming element can be either a clocked flip-flop or a clocked latch. The clocked-retiming element 212 is clocked by a clock signal 222, located at the end of the buffer chain 221. The output of the clocked-retiming element 212 is input into a driver component 213. The driver component 213 drives the matched data signal 214 across die interconnects 230 from Die-1 201 to Die-2 202. The received data signal is input to buffer 215. The output of buffer 215 is connected to the input of clocked-retiming element 216. The clocked-retiming element 216 is clocked by the matched receiver clock 227 and generates the receiver data 217. Here, a matched receiver clock means that the timing of the receiver clock 227 that is used to trigger or gate the clocked-retiming element 216 occurs substantially in the middle of a data cycle. The matched receiver clock 227 is received from a buffer or buffer chain 226. The input to the buffer or buffer chain 226 is connected to the clock die interconnect 231.

The clock signal 222 is generated by inputting a system clock 220 from Die-1 201 into a buffer chain 221. System clock 220 can be a system clock utilized on Die-1 201, or another clock associated with data 211 being transferred between Die-1 201 and Die-2 202. The clock signal 222 is input into flip-flop 223. The flip-flop 223 generates an output 224 that is connected to the input of driver 225. The driver 225 transmits the clock to the Die-2 202 via clock die interconnect 231.

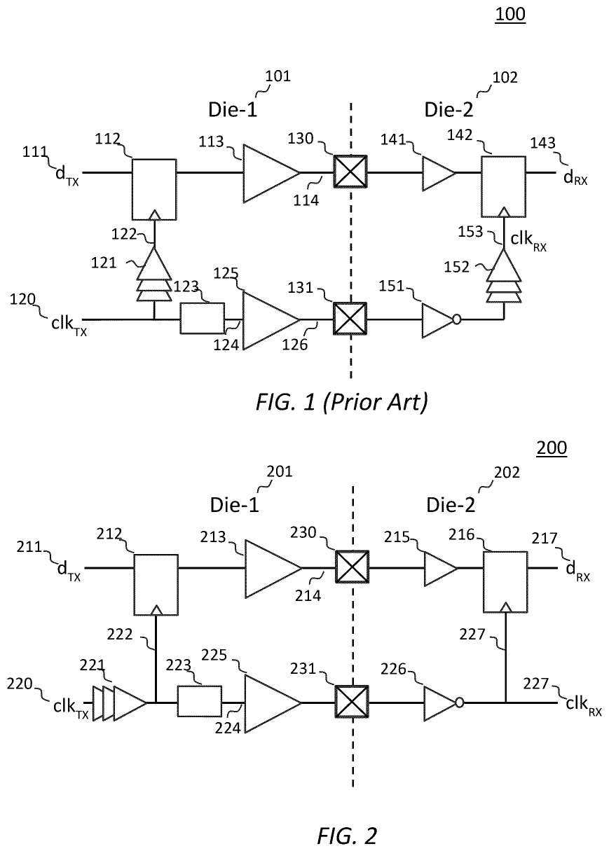

In contrast to the prior art described in FIG. 1, the embodiment shown in FIG. 2 eliminates the need to match the delays of circuitry that exist on the two different dies-i.e., no circuitry on Die-1 201 must match any circuitry on Die-2 202 in order to maintain optimal timing alignment between the clock and the data. This is achieved by constraining the number of data lines within the bundle—for example, to twenty—such that buffer 226 of FIG. 2 is sufficient to drive all of the receive retiming elements 216. In contrast to the prior art in FIG. 1, the clock buffer chain on the transmitter (221 of FIG. 2) is now moved to prior to the point of physical divergence between the transmitted data and the transmitted clock, and hence the nominal delay of that buffer chain does not influence the timing margin of the data relative to the clock at the receiver.

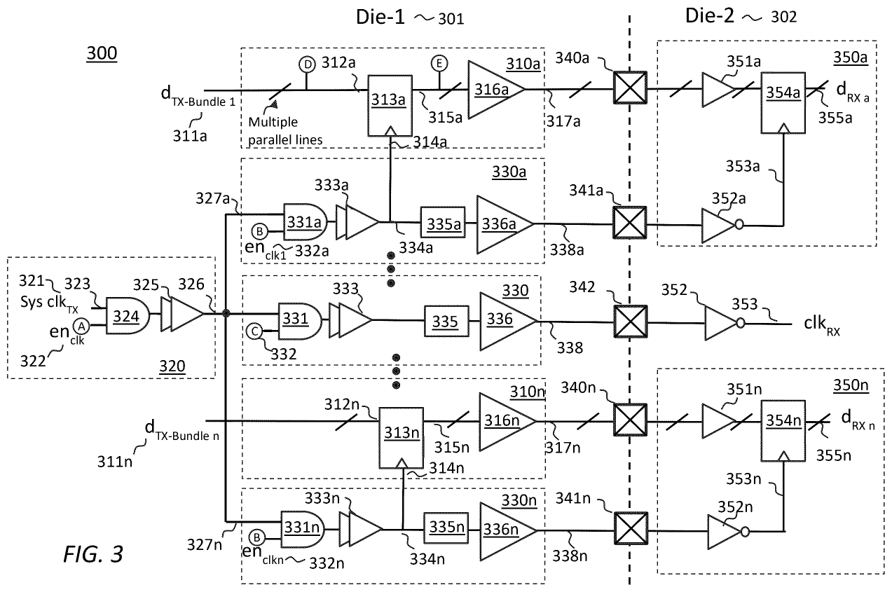

Referring to FIG. 3, an example embodiment is shown of a schematic diagram 300 illustrating synchronization circuitry for transmitting a data bundle and clock between circuitry on one semiconductor die, Die-1 301, and another semiconductor die, Die-2 302, in accordance with an embodiment of the disclosed invention. A data bundle is a number or plurality of data lines that transmit data in parallel from one die and are received on a second die. Preferably, the number of lines is between sixteen and twenty data lines within a bundle. The interconnection between Die-1 301 and Die-2 302 is through data-bundle die interconnects 340a-n, bundle-clock interconnects 341a-n, and receive-clock die interconnect 342 that include but are not limited to die pads, wires, or any other known technique for interconnecting semiconductor dies in a 2.5/3D semiconductor architecture or any future architecture.

The circuitry on Die-1 301 includes the following subcircuits: at least one data-bundle circuit 310a-n, a source-clock circuit 320, at least one bundle-clock circuit 330a-n, and a receive-clock circuit 330. The receive-clock circuit 330 has a similar structure as the bundle-clock circuit 330a-n. Thus, matched clocks 338 and 338a-n will have similar delay characteristics that are transferred to Die-2 302 over the receive-clock die interconnect 342 and bundle-clock die interconnects 341a-n. Further, if a pair of associated data-bundle circuits and bundle-clock circuits are formed in physical proximity (collocated) on Die-1 301, then the effects of temperature, voltage, and semiconductor process variations can have similar delay effects on signals within a data-bundle circuit and its associated bundle-clock circuit. Note that the dashed lines around the subcircuits indicate a logical grouping of functions to help in the description of the circuits.

The source-clock circuit 320 receives system clock 321 from within Die-1 301 on input 323. Additionally, the source-clock circuit 320 can receive a source-clock enable 322 input to clock-AND gate 324. System clock 321 is associated with generating data to be transferred to Die-2 302. In a bundle, parallel data is grouped into a transmit data bundle 311a. The transmit data bundle 311a data is synchronized with clocked-retiming element 313a using a transmit-bundle clock 334a from the associated bundle-clock circuit 330a received from clocking element 313a. The resulting transmit-bundle data 317a and matched clock 338a are transmitted over data-bundle die interconnects 340a and bundle-clock die interconnect 341a to Die-2 302. This data-bundle circuit 310a is duplicated for each data bundle.

The system clock 321 is typically used by other circuitry (not shown) on Die-1 301.

Each transmit data bundle 311a-n includes multiple input data lines, typically around twenty (20). Sixteen (16) to thirty-two (32) data lines are other common groupings that do not exceed the maximum fanout loading of inverting buffers or inverting buffer chain (352a-n) within the RX circuits. However, the invention contemplates fewer or a greater number of data lines. The use of the term data bundles is not limited to only data lines but can include other types of information, including but not limited to address lines or other bundles of parallel information that are to be transmitted from one die to another die.

Referring to source-clock circuit 320, a system clock 321 and a source-clock enable 322 is input into a clock-AND gate 324. The source-clock enable 322 can be used to enable and disable the source-clock circuit 320, which results in providing a source clock 326 to the bundle-clock circuits 330a-n. The circuitry for only one clock path is shown going through the source-clock circuit 320, the receive-clock circuit 330, the receive-clock die interconnect 342, and inverting buffer or inverting buffer chain 352, resulting in receiver clock 353 on Die-2 302.

Redundant clock circuitry can be provided that duplicates the circuitry path through the receive-clock circuit 330, to the receive-clock die interconnect 342, through the inverting buffer or inverting buffer chain 352, and thereby providing the receiver clock 353. In one embodiment, the receive-clock circuit 330 can include an AND gate 331 to enable or disable the receive-clock circuit 330. The receive-clock circuit enable 332 is used to enable the source clock 326 within the receiver-clock circuit. The receive-clock circuit enable 332 can be generated by another circuit or tied to an enabled value.

The redundant clock can be enabled and used by Die-2 302 in situations where there is a problem with the source-clock circuitry 320 or the receive-clock die interconnect 342 between Die-1 301 and Die-2 302. For example, and not by way of limitation, the physical connection between Die-1 301 and Die-2 302 can be defective. During system initiation of the circuitry on Die-1 301 and Die-2 302, the detection of a clocking defect can result in the enabling of a redundant clock circuit (not shown) and configuring Die-2 302 to use the clock signal provided from the redundant clock path (not shown).

The source clock AND gate 324 output is input into a buffer chain 325. The buffer chain output 326 is connected to each of the bundle-clock circuits 330a-n and the receive-clock circuit 330. The buffer chain 325 is used to maintain the fidelity of the source clock 326 signal from the clock-AND gate 324 as the source clock 326 is distributed to the inputs 327a-n of the bundle-clock circuits 330a-n.

Referring to the data-bundle circuits 310a-n, each transmit data bundle 311a, within a data-bundle circuit 310a represents multiple parallel transmit data lines, typically between sixteen and twenty. This group of transmit data lines is referred to as a transmit data bundle 311a.

The transmit data bundles 311a-n are coupled to the clocked-retiming element inputs 312a-n of the clocked-retiming elements 313a-n. The clocked-retiming elements 313a-n can be a flip-flop, latch, or any other semiconductor element that provides a timed regeneration of an input signal based on receiving a clock. The clocked-retiming element 313a represents multiple clocked-retiming elements, one for each data line of the transmit data bundle 311a. This structure is repeated for each of the data-bundle circuits 310a-n, where transmit data bundle 311a lines are connected to the clocked-retiming elements input 312a-n. The clocked-retiming elements 313a-n, for each line within the transmit data bundles 311a-n, are clocked by the respective transmit-bundle clock 334a-n, input on the clocked-retiming element clock input 314a-n. The clocked-retiming element data outputs 315a-n are triggered or gated on the rising edge of the transmit-bundle clocks 334a-n. The clocked-retiming elements data outputs 315a-n are input into line drivers 316a-n. Each line driver 316a provides signal drivers for the multiple lines that form a bundle. The line drivers 316a-n outputs transmit-bundle data 317a-n that are connected to data-bundle die interconnects 340a-n. The data-bundle die interconnect 340a represents interconnects for multiple lines, one for each of the transmit data lines within a data bundle.

Referring to the bundle-clock circuits 330a-n, each bundle-clock circuit inputs the source clock 326, and a bundle-clock enable 332a-n. The source clock 326 is received from the output of the source-clock circuit 320. The source clock 326 is connected to inputs 327a-n of bundle-clock AND gates 331a-n of each bundle-clock circuit 330a-n. The other inputs to the bundle-clock AND gates 331a-n are connected to the bundle-clock enables 332a-n for each bundle-clock circuit 330a-n. The outputs of the bundle-clock AND gates 331a-n are input into buffer chains 333a-n. The buffer chain outputs 334a-n are connected to the clocked-retiming element inputs 314a-n of the respective data-bundle circuit 310a-n. The buffer chain 333a-n generates, the transmit-bundle clocks 334a-n and is used by the clocked-retiming elements 313a-n to synchronize the transmit data bundle 311a-n. Additionally, each of the buffer chain outputs 334a-n is connected to an input of clock-delay elements 335a-n. The clock-delay elements 335a-n are designed to replicate the delay of clocked-retiming element 313a-n thereby generating a matched clock 338a-n with the transmit-bundle data. Note there is only one clock-delay element 335a-n within each bundle-clock circuit 330a-n. The output of the clock-delay element 335a-n is connected to the input of clock drivers 336a-n. Again, there is only one clock driver 336a-n within each bundle-clock circuit 330a-n and a single line transmitting the clock associated with the respective data-bundle circuit 310a-n. Each clock driver's 336a-n output 338a-n is connected to the bundle-clock die interconnects 341a-n.

Die-2 302 receiver circuits 350a-n interfaces with the data-bundle die interconnects 340a-n and bundle-clock die interconnects 341a-n. The data-bundle die interconnects 340a-n connect to buffers or buffer chains 351a-n. The receiver-retiming elements 354a-n each receive a clock from the inverting buffer or inverting buffer chain 352a-n. The output of the inverting buffer or inverting buffer chain 352a-n provides, for each bundle, a clock to multiple receiver-retiming elements 354a-n, one for each received data line. The data-bundle die interconnects 340a-n are connected to the previously mentioned buffers 351a-n, and each line is input into a receiver-retiming element 354a-n. The output of the receiver-retiming elements 354a-n outputs receiver-bundle data 355a-n.

A matched clock signal is received from bundle-clock die interconnects 341a-n, which is input into the inverting buffer or inverting buffer chain 352a-n. The inverting buffer or inverting buffer chain output generates a receiver clock 353a-n, which is used to clock the receiver-retiming elements 354a-n. Each receiver-retiming element 354a-n is configured to trigger on the rising edge of the received transmit clock inputs 353a-n.

The receiver clock 353 is a clock that can be used by circuitry (not shown) on a Die-2 302 that may need a matched clock from Die-1 301, which is connected to the receive-clock die interconnect 342 through inverting buffer or inverting buffer chain 352. This clock should have substantially the same delay characteristics as the bundle-clock circuits 330a-n. Thus, receiver clock 353 is matched with the receiver-bundle data 355a, which means that it is aligned with the receiver-bundle data 355a-n. This receiver clock 353 can be used by other circuitry on Die-2 302 for further processing of the receiver-bundle data 355a-n.

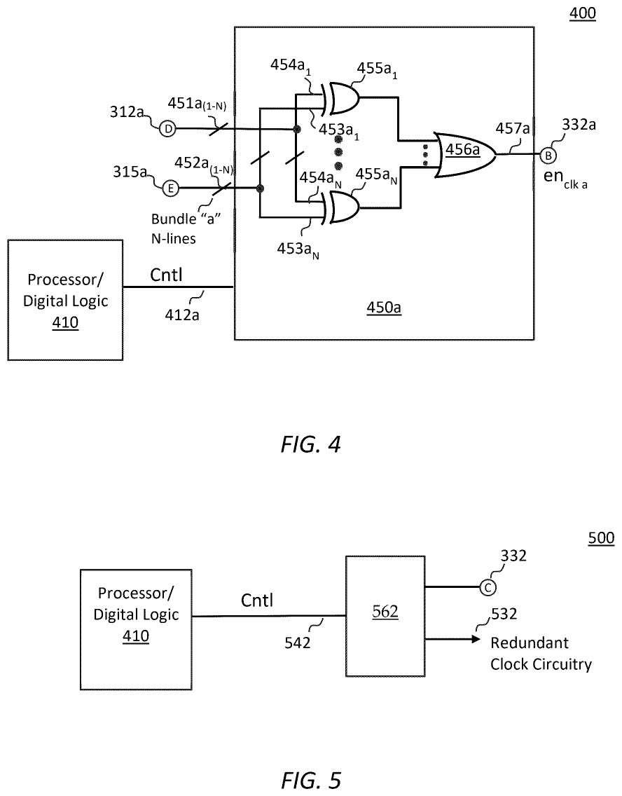

Referring to FIG. 4, circuit schematic 400 relates to a system where the clocking of each data bundle can be individually enabled and disabled. The benefit of disabling the clocking to a data-bundle circuit is power savings, which is achieved by eliminating the clocking of some of the circuit components in the bundle-clock circuit 330a and the data-bundle circuit 310a. In this example, the bundle-clock circuit 330a—FIG. 3 and data-bundle circuit 310a—FIG. 3 is disabled. In another scheme utilizing the data-bundle circuit 310a, enabling and disabling capability can be used to provide a backup or redundant data-bundle circuit in case of a circuit failure or failed connection between Die-1 301 and Die-2 302.

Circuit schematic 400 illustrates a circuit that can be used, in conjunction with the circuit 300 of FIG. 3 to provide data idle detection. Data idle detection is not required for the operation of the circuit 300 of FIG. 3 or within a system that utilized the circuit 300 of FIG. 3. The bundle-clock AND gates 331a-n could be eliminated or the bundle-clock input enables 332a-n tied high.

In schematic 400, an embodiment shows inputs, outputs, and components for generating a bundle-enable output 457a. The bundle-enable output 457a is connected to a bundle-clock input enable 332a. The bundle-clock input enable 332a enables and disables the bundle-clock circuit 320a, as shown in FIG. 3. In another embodiment, control and configuration of the components 450a features can be provided by a digital processor or digital logic/finite state machine 410 interfacing with component 450a over a communication link or bus 412a. A duplicate of component 450a can be provided for each of the other bundle-clock enable inputs 332a-n.

Component 450a generates a bundle-enable output 457a connected to the bundle-clock output enable 332a-FIG. 3. The generation of the bundle-enable output 457a is based on the clocked-retiming element inputs 312a-FIG. 3 and the clocked-retiming element output 315a, which are provided as inputs 451a_{(1-N)} and 452a_{(1-N)}. Thus, the input 451a_{(1-N)} represents the current transmit data bundle value, and 452a_{(1-N)} represents the prior transmit data bundle value. If the transmit data bundle values do not change between the current and prior transmit data bundle values, then by not enabling the bundle-clock circuit 320a—FIG. 3, the power of clocking the associated circuits is saved when identical data is sent to the data-bundle die interconnects 340a.

In one embodiment of component 450a, the circuit consists of components that perform a logic XOR 455a (1-N) on each of the “N” lines of the prior and current transmit data values. These current and prior transmit data values are provided from the bundle of data lines 312a and 315a, as shown in FIG. 3, and are provided as inputs 451a_{(1-N)} and 452a_{(1-N)} to component 450a. These prior and current transmit values are inputs 454a_{(1-N)} into logic XOR components 455a₁ to 455a_{N}. The output of the logic XOR components 455a (1-N) are input into a logic OR component 456a. If any of the transmit data bundle lines change between the current and prior cycle, then the output of the XOR component will be a logical one into the OR component 456a input, and the logic OR will generate a logical one at the output 457a.

In another embodiment, a processor or digital logic/finite state machine 410 can be used to enable and disable the bundle-clock circuits 330a-n. This control can be used to remove misfunctioning bundle-clock circuits and enable a redundant bundle-clock circuit (not shown). This feature can be utilized when a bundle-clock circuit 330a-n is detected. An alternative bundle-clock circuit and data-bundle circuit can be enabled by the processor or digital logic/finite state machine 410 to replace the defective circuit. Other circuitry (not shown) would be required to reroute the data within Die-1 301 to the redundant circuit.

Referring to FIG. 5, illustrates circuitry 500 for use within a system with redundant circuitry for generating a backup receive clock between Die-1 301 and Die-2 302. This redundant circuitry is not shown in this figure or FIG. 3. In one embodiment, if a failure is detected in the receiver clock 353, the system can be configured with backup or redundant clock circuitry that, when enabled, provides a replacement clock. The failure could occur in the source-clock circuit 320, the receive-clock circuit 330, the receive-clock die interconnect 342, or a combination thereof. The enabling and disabling of the clock circuitry 360 is provided by component 362, which can be under the control of a digital processor or digital logic/finite state machine 410.

The digital processor or digital logic/finite state machine 410 can control component 562 through a control interface 542. One embodiment of this circuit component 562 can be a decoder circuit that generates the enables a receive-clock circuit enable 332 or 532 for a redundant receive-clock circuit (not shown). A POSITA in digital logic design would know how to build the logic of component 562 to generate the enables.

1. A circuit for transmitting high speed data across a multi-die, three-dimensional semiconductor device, the circuit comprising:
input data on one or more input lines containing information to be communicated from a first die to a second die over die interconnects;
one or more transmit retiming elements coupled to each of the one or more input lines to receive, retransmit, control timing of the input data and generating transmit data sent over one or more transmit lines coupled to the die interconnects;
a first clock circuit receiving a system clock signal at the first die, generating a matched source clock from the system clock, synchronizing the input data on the one or more transmit lines, the system clock signal coupled to and operable on the first clock circuit; and
a first receiver circuit contained on the second die and coupled to the matched source clock signal from the first die and the one or more transmit lines from the first die, the matched source clock signal being matched to the received data from the one or more transmit lines from the first die and the received data synchronize by one or more receive retiming elements.

2. The circuit of claim 1, wherein the matched source clock is aligned with substantially in the center of the data on the one or more input lines.

3. The circuit of claim 2, wherein the one or more input lines, the one or more transmit retiming elements, and the first timing circuit are physically collocated on the first die and first die delay characteristics of the one or more input lines, and one or more transmit retiming elements are substantially the same as the delay characteristics of the first clock timing circuit.

4. The circuit of claim 3, wherein the first die delay characteristics result from first die variations in one or more of operating temperature, operating voltage, and fabrication process for die 1.

5. The circuit of claim 1, wherein the one or more transmit retiming elements and the one or more receiver retiming elements are clocked flip-flops.

6. The circuit of claim 1, wherein the one or more retiming elements and one or more receiver-retiming elements are sixteen to twenty retiming elements and receiver-retiming elements.

7. The circuit of claim 1, further comprising a first clock circuit enable.

8. The circuit of claim 7, further comprising:
a circuit to logically XOR a prior cycle's transmit data with a current cycle of transmit data thereby generating a logical XOR output for each line of the input data; and
a circuit to input the logical XOR for each line of the input data and perform a logical OR on each of the logical XOR output thereby generating a bundle-enable output to an AND gate to enable the matched source clock if any of the transmit data transitions between the prior cycle and the current cycle.

9. The circuit of claim 1, further comprising a third die containing a third clock retiming circuit coupled to the matched source clock signal from the first die and the one or more transmit lines from the first die, the matched source clock signal being matched to the received data from the one or more transmit lines from the first die and the received data synchronized by one or more third die receive retiming elements.

10. A circuit for providing matched clocks for transmitting data bundles from a first semiconductor die to a second semiconductor die comprising:
a first semiconductor die further comprising:
a source-clock circuit, receiving a system clock and outputting a source clock;
a bundle-clock circuit further comprising:
a bundle-clock input connected to the source clock;
a transmit-bundle clock output providing a transmit-bundle clock; and
an interconnect transmit-bundle clock output connected to a bundle-clock die interconnect;
a data-bundle circuit comprising:
a plurality of transmit data inputs;
a data-bundle clock input receiving the transmit-bundle clock output from the bundle-clock circuit; and
a plurality of transmit-data outputs coupled to a plurality of data-bundle die interconnects, the data-bundle circuit configured to output data on a rising edge of a transmit-bundle clock; and
a receive-clock circuit configured to generate a receive-transmit clock, the receive clock circuit receiving the source clock and outputting the receive-transmit clock to a receive-clock die interconnect, the receive-transmit clock having substantially the same delay as the interconnect transmit-bundle clock.

11. The circuit of claim 10, wherein the source-clock circuit comprises:
a clock-AND gate further comprising:
a clock enable input;
a system clock input; and
an enabled-clock output; and
a clock buffer chain connected to a clock-AND gate output and the clock buffer chain outputting the source clock.

12. The circuit of claim 10, wherein the bundle-clock circuit further comprises:
a bundle-clock AND gate further comprising:
a bundle-clock enable input;
the bundle-clock input; and
an enabled bundle-clock output, wherein the bundled-clock buffer chain input is connected to the enabled bundle-clock output and the bundled-clock buffer chain output connected to the transmit-bundle clock;
a bundle flip-flop further comprising:
a bundle-clock flip-flop input connected to the bundled-clock buffer chain output; and
a bundle flip-flop output; and
a bundle-clock driver further comprising:
a bundle-clock driver input connected to the delay element output; and
a bundle-clock driver output coupled to the bundle-clock die interconnect and transmitting the interconnect transmit-bundle clock.

13. The circuit of claim 10, wherein the data-bundle circuit further comprises:
a plurality of clocked-retiming elements connected and associated with each of the plurality of the transmit data inputs, wherein the data-bundle clock inputs are coupled to the plurality of clocked-retiming elements;
a plurality of clocked-retiming element outputs; and
a plurality of data drivers further comprising:
a plurality of driver inputs coupled to the clocked-retiming element outputs; and
a plurality of driver outputs coupled to the plurality of data-bundle die interconnects.

14. The circuit of claim 13, further comprising a plurality of bundle-clock circuits and a plurality of data-bundle circuits.

15. The circuit of claim 14, wherein the plurality of transmit data inputs, the plurality of clocked-retiming elements, and the plurality of data drivers is between sixteen and twenty.

16. The circuit of claim 13, further comprising:
a bundle evaluation circuit comprising:
data inputs coupled to the plurality of transmit data inputs;
prior data inputs coupled to the plurality of transmit-data outputs; and
a bundle-enable output connected to the bundle-clock enable input, wherein the bundle-enable output further comprises:
a XOR circuit to logically XOR each of the data inputs with each of the prior data inputs thereby generating a plurality of logical XOR outputs; and
an OR circuit to input the plurality of logical XOR outputs thereby generating the bundle-enable output to an AND gate enabling the transmit bundle clock.

17. The circuit of claim 10, further comprising:
a second semiconductor die comprising:
a receiving semiconductor die circuit connected to the plurality of data-bundle die interconnects and the bundle-clock die interconnect.

18. The circuit of claim 17, wherein the receiving semiconductor die circuit further comprises:
a plurality of second die buffers comprising:
a plurality of second-die buffer inputs connected to respective data-bundle die interconnects;
a plurality of second die buffer outputs; and
a plurality of receiver clocked-retiming elements, the receiver plurality of clocked-retiming elements comprising:
a plurality of receiver clocked-retiming element inputs connected to the respective plurality of second die buffer outputs;
a plurality of receiver clocked-retiming element outputs, wherein each of the plurality of receiver clocked-retiming element outputs are triggered on the rising edge of the receiver clocked-retiming element clock inputs; and
a plurality of receiver clocked-retiming element inverted clock inputs coupled to the bundle-clock die interconnect.

19. A method for providing matched clocks for transmitting data bundles from a first semiconductor die to a second semiconductor die comprising:
receiving a system clock;
outputting a source clock to a bundle-clock circuit;
receiving a plurality of transmit data inputs;
generating a transmit-bundle clock from the system clock configured so that a rising edge of the transmit-bundle clock is substantially centered in a data cycle;
retiming the transmit data inputs on the rising edge of the transmit-bundle clock;
outputting the transmit-bundle clock to a bundle-clock die interconnect; and
outputting a plurality of transmit data on the rising edge of the transmit-bundle clock to data-bundle die interconnects.

20. The method of claim 19, further comprising:
receiving from a bundle-clock die interconnect on a second semiconductor die the transmit-bundle clock;
receiving from the data-bundle die interconnects on the second semiconductor die the plurality of transmit data; and
retiming the plurality of transmit data on a rising edge of the transmit-bundle clock.

21. The method of claim 20, further comprising:
receiving from the bundle-clock die interconnect on the second semiconductor die the transmit-bundle clock.
